(19) United States
(12) Patent Application Publication
(10) Pub. No.: US 2015/0294455 A1
(43) Pub. Date: Oct. 15, 2015

(54) METHODS OF TESTING PATTERN RELIABILITY AND SEMICONDUCTOR DEVICES

(71) Applicant: Samsung Electronics Co., Ltd., Suwon-si (KR)

(72) Inventors: Jeong-Jin LEE, Asan-si (KR); Seung-Hwa OH, Hwaseong-si (KR); Chan HWANG, Seoul (KR)

(21) Appl. No.: 14/581,232

(22) Filed: Dec. 23, 2014

(30) Foreign Application Priority Data
Apr. 9, 2014 (KR) 10-2014-0042565

(51) Int. Cl. G06T 7/00; G06T 1/00; G06K 9/46; H01L 23/544; G01N 21/88

(52) U.S. Cl. CPC G06T 7/0004; H01L 23/544; G01N 21/8851; G06K 9/46; G06T 1/00; G01N 2021/8854; G01N 2021/8887; G06K 2009/4666

(57) ABSTRACT

Provided are methods of testing pattern reliability and methods of testing a semiconductor device using the same. A method of testing pattern reliability may include acquiring an optical image of a wafer on which a plurality of patterns are formed, evaluating degrees of damage of ones of the plurality of patterns based on the optical image, determining a respective reliability of the ones of the plurality of patterns according to the evaluated respective degrees of damage, and mapping the reliability of the ones of the plurality of patterns based on locations of the respective patterns on the wafer.

### CROSS-REFERENCE TO RELATED APPLICATION

This application claims priority under 35 U.S.C. §119 to Korean Patent Application No. 10-2014-0042565, filed on Apr. 9, 2014 in the Korean Intellectual Property Office, the disclosure of which is hereby incorporated herein by reference in its entirety.

### FIELD

Some embodiments of inventive concepts relate to semiconductor device fabrication and, more specifically, methods of testing pattern reliability.

### BACKGROUND

A method of fabricating a semiconductor device includes a plurality of unit processes such as photolithography process. In the method of fabricating the semiconductor device, patterns are formed on scribe lanes of a wafer for aligning the wafer before each of the unit processes. Various testing methods of the patterns and the semiconductor device have been proposed for accurate alignment.

### SUMMARY

According to some embodiments of inventive concepts, methods of testing pattern reliability are provided. A method may include acquiring an optical image of a wafer on which a plurality of patterns are formed, evaluating respective degrees of damage of ones of the plurality of patterns based on the optical image, determining a respective reliability of the ones of the plurality of patterns according to the evaluated respective degrees of damage, and mapping the reliability of the ones of the plurality of patterns based on locations of the respective patterns on the wafer.

In some embodiments, evaluating the degrees of damage may include dividing the ones of the plurality of patterns into a number of divided areas, detecting a respective signal value for each of the divided areas from the acquired optical image, and calculating a respective standard deviation for the ones of the plurality of patterns using the detected signal values and an average signal value of the detected signal values.

In some embodiments, the determining of the reliability of the patterns may include determining a pattern to be an unreliable pattern when a degree of damage thereof is greater than a reference degree of damage.

In some embodiments, the mapping of the reliability may include distinguishing a pattern determined to be reliable and a pattern determined to be unreliable on a map based on the respective locations of the pattern determined to be reliable and the pattern determined to be unreliable according to the reliability of the determined ones of the plurality of patterns.

According to some embodiments of inventive concepts, methods of testing a semiconductor device using a pattern reliability test are provided. A method may include acquiring an optical image of a wafer on which a plurality of patterns is formed. The method may include evaluating respective degrees of damage of ones of the plurality of patterns based on the optical image. The method may include determining respective reliabilities of the ones of the plurality of patterns according to the evaluated respective degrees of damage. The method may include mapping the reliabilities of the ones of the plurality of patterns based on locations of the respective patterns on the wafer. The method may include performing a test on the mapped patterns. The method may include correcting a recipe used to perform a process according to a result of the test.

In some embodiments, the performing of the test may include performing the test on patterns mapped as reliable patterns among the mapped patterns.

In some embodiments, the performing of the test may include removing result values of the test corresponding to patterns mapped as unreliable patterns after performing the test on the mapped patterns.

In some embodiments, the ones of the patterns may include a respective overlay mark.

In some embodiments, the evaluating of the respective degrees of damage of the ones of the plurality of patterns may include evaluating the respective degrees of damage of respective target overlay marks of the respective overlay marks.

In some embodiments, the method may include monitoring a unit process performed on the target overlay mark to determine a cause of an error.

In some embodiments, the unit process may include at least one of a chemical mechanical polishing (CMP) process and an etching process.

In some embodiments, the determining of the reliability of the patterns may include determining a set percentage of the ones of the patterns with the highest degrees of damage to be unreliable and may include determining the remaining patterns to be reliable.

In some embodiments, the set percentage may be around 30% or more.

In some embodiments, the correcting of the recipe may correct the recipe with respect to a photolithography process.

In some embodiments, the performing of the test may include measuring an overlay and selecting an outlier degree of damage having a degree of damage greater than a set degree of damage or greater than a statistical reference degree of damage among the measured degrees of damage.

According to some embodiments of inventive concepts, methods are provided. A method may include acquiring an optical image of a wafer including a plurality of overlay marks. The method may include evaluating respective degrees of damage of ones of the plurality of overlay marks based on the optical image. The method may include selecting a reliable overlay mark from the ones of the plurality of overlay marks based on the evaluated degrees of damage. The method may include correcting a recipe of a process for producing wafers based on the reliable overlay mark.

In some embodiments, the plurality of overlay marks may include a plurality of target overlay marks and a plurality of upper overlay marks on the plurality of target overlay marks. Evaluating respective degrees of damage may include measuring respective degrees of an overlap between ones of the plurality of target overlay marks and corresponding ones of the plurality of upper overlay marks.

In some embodiments, the ones of the plurality of overlay marks may include a respective plurality of patterns, and the evaluating respective degrees of damage of ones of the plurality of overlay marks may include averaging standard deviations of signal values of the respective plurality of patterns based on the acquired optical image.

In some embodiments, the correcting the recipe of the process may include measuring a plurality of signals detected from the reliable overlay mark. The correcting the recipe of the process may include selecting an overlay outlier from the plurality of signals. The value of the overlay outlier may be greater than a set value or a statistical reference value. The correcting the recipe of the process may include determining an overlay value by overlaying and averaging ones of the plurality of signals that are not selected as the overlay outlier.

In some embodiments, evaluating respective degrees of damage of ones of the plurality of overlay marks may include calculating a standard deviation of a plurality of detected signal values corresponding to a plurality of areas of a respective one of the plurality of overlay marks based on the optical image.

According to some embodiments of inventive concepts, an apparatus of testing pattern reliability may include an optical image acquisition unit configured to scan a surface of a wafer and acquire an optical image, a computing system configured to analyze the image of the wafer acquired from the optical image acquisition unit and test reliability of patterns, a server configured to receive data of a test result or transmit various information about the test requirements of the wafer through communication with the computing system, and a database configured to store data received through the server and various information about the wafer used in the test.

In some embodiments, the computing system may include an image analyzing unit configured to analyze the optical image of the wafer received from the optical image acquisition unit, a pattern degree of damage evaluation unit configured to evaluate degrees of damage of the patterns using an image signal value analyzed by the image analyzing unit, a pattern reliability mapping unit configured to determine the reliability of the patterns and map the determined reliability into a wafer map according to the degrees of damage evaluated in the pattern degree of damage evaluation unit, and a storage unit configured to store data to operate the computing system, or data of a test result, and a mathematical calculation algorithm for analyzing the optical image, or testing the pattern reliability.

According to some embodiments of inventive concepts, a method of testing a semiconductor device using a pattern reliability test may include acquiring an optical image of a wafer on which a plurality of patterns are formed, evaluating degrees of damage of the patterns, determining reliability of the patterns according to the evaluated degrees of damage, mapping the reliability of the patterns, testing the mapped patterns, and correcting a recipe to perform a process according to a result of the test.

According to some embodiments of inventive concepts, an apparatus of testing a semiconductor device using a pattern reliability test may include an optical image acquisition unit configured to scan a surface of a wafer and acquire an optical image, a computing system configured to analyze the image of the wafer acquired from the optical image acquisition unit and test reliability of patterns, a server configured to receive data of a test result or transmit various information of the test requirements of the wafer through communication with the computing system, a database configured to store data received through the server and various information about the wafer used in the test, and process equipment configured to perform a unit process on the wafer, transfer information thereof to the computing system or the server, and perform the unit process on the wafer by a corrected recipe received from the computing system or the server.

According to some embodiments of inventive concepts, a method of measuring an overlay using a pattern reliability test may include acquiring an optical image of a wafer on which a plurality of overlay marks including target overlay marks are formed, evaluating degrees of damage of the target overlay marks, determining reliability of the target overlay marks according to the evaluated degrees of damage, mapping the reliability of the target overlay marks, testing the overlay marks, and correcting a recipe for performing a process according to a result of the test.

It is noted that aspects of inventive concepts described with respect to one embodiment, may be incorporated in a different embodiments although not specifically described relative thereto. That is, all embodiments and/or features of any embodiments can be combined in any way and/or combination. These and other objects and/or aspects of present inventive concepts are explained in detail in the specification set forth below.

### BRIEF DESCRIPTION OF THE DRAWINGS

The accompanying figures are included to provide a further understanding of present inventive concepts, and are incorporated in and constitute a part of this specification. The drawings illustrate some embodiments of present inventive concepts and, together with the description, serve to explain principles of present inventive concepts.

FIG. 1 is a flowchart illustrating a method of testing pattern reliability according to some embodiments of inventive concepts;

FIG. 2 is a plan view schematically illustrating a wafer, on which a pattern is formed for a method of testing pattern reliability, according to some embodiments of inventive concepts;

FIGS. 3A to 3C are signal waveforms illustrating signal values detected to test a deformation degree of a pattern in a method of testing pattern reliability according to some embodiments of inventive concepts;

FIG. 4 is a plan view schematically illustrating a wafer map mapped by a method of testing pattern reliability according to some embodiments of inventive concepts;

FIG. 5 is a block diagram schematically illustrating an apparatus of testing pattern reliability according to some embodiments of inventive concepts;

FIG. 6 is a flowchart illustrating a method of testing a semiconductor device using a pattern reliability test according to some embodiments of inventive concepts;

FIG. 7 is a block diagram schematically illustrating an apparatus of testing a semiconductor device using a pattern reliability test according to some embodiments of inventive concepts;

FIG. 8 is a flowchart illustrating a method of measuring an overlay using a pattern reliability test according to some embodiments of inventive concepts;

FIG. 9 is an cross-sectional view schematically illustrating a wafer during formation of an overlay mark in a method of measuring an overlay using the method of testing pattern reliability according to some embodiments of inventive concepts;

FIG. 10 provides plan views illustrating overlay marks in a method of measuring an overlay using the method of testing pattern reliability in accordance with some embodiments of inventive concepts;

FIG. 11 provides wafer maps illustrating measured overlay values, corrected overlay values, and residual overlay values in a method of measuring an overlay using the method of testing pattern reliability according to some embodiments of inventive concepts; and

FIG. 12 is a graph of residual overlay values according to a reference value for checking pattern reliability in a method of measuring an overlay using the method of testing pattern reliability in accordance with some embodiments of inventive concepts.

### DETAILED DESCRIPTION OF THE EMBODIMENTS

Embodiments are described in detail with reference to the accompanying drawings in which some embodiments are shown. Present inventive concepts may, however, be embodied in different forms and should not be construed as being limited only to the illustrated embodiments set forth herein. Rather, these embodiments are provided as examples so that this disclosure will be thorough and complete and will fully convey the concepts of inventive concepts to those skilled in the art. Unless otherwise noted, like reference numerals denote like elements throughout the attached drawings and written description, and thus descriptions may not be repeated.

The terminology used herein is for the purpose of describing particular embodiments only and is not intended to be limiting of inventive concepts. As used herein, the singular forms “a,” “an,” and “the” are intended to include the plural forms as well, unless the context clearly indicates otherwise. As used herein, the term “and/or” includes any and all combinations of one or more of the associated listed items. It will be further understood that the terms “comprises,” “comprising,” “includes,” and/or “including,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being “on,” “connected to,” or “coupled to” another element or layer, it can be directly on, connected or coupled to the other element or layer or intervening elements or layers may be present. In contrast, when an element is referred to as being “directly on,” “directly connected to,” or “directly coupled to” another element or layer, there are no intervening elements or layers present. As used herein, the term “and/or” includes any and all combinations of one or more of the associated listed items.

Spatially relative terms, such as “beneath,” “below,” “lower,” “above,” “upper,” and the like, may be used herein for ease of description in describing one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein may be interpreted accordingly.

The exemplary embodiments of inventive concepts will be described with reference to cross-sectional views and/or plan views, which are ideal exemplary views. Thicknesses of layers and areas may be exaggerated for effective description of the technical contents in the drawings. Forms of the embodiments may be modified by the manufacturing technology and/or tolerance. Therefore, the embodiments of inventive concepts are not intended to be limited to illustrated specific forms, and include modifications of forms generated according to manufacturing processes. For example, an etching area illustrated at a right angle may be round or have a predetermined curvature. Therefore, areas illustrated in the drawings have overview properties, and shapes of the areas are illustrated special forms of the areas of a device, and are not intended to limit the scope of the inventive concepts.

Unless otherwise defined, all terms (including technical and scientific terms) used herein have the same meaning as commonly understood by one of ordinary skill in the art to which present inventive concepts belong. It will be further understood that terms, such as those defined in commonly used dictionaries, should be interpreted as having a meaning that is consistent with their meaning in the context of the relevant art and/or the present specification and will not be interpreted in an idealized or overly formal sense unless expressly so defined herein.

As appreciated by the present inventive entity, devices and methods of forming devices according to various embodiments described herein may be embodied in microelectronic devices, such as integrated circuits, wherein a plurality of devices according to various embodiments described herein are integrated in the same microelectronic device. Accordingly, the cross-sectional view(s) illustrated herein may be replicated in two different directions, which need not be orthogonal, in the microelectronic device. Thus, a plan view of the microelectronic device that embodies devices according to various embodiments described herein may include a plurality of the devices in an array and/or in a two-dimensional pattern that is based on the functionality of the microelectronic device. The devices according to various embodiments described herein may be interspersed among other devices depending on the functionality of the microelectronic device.

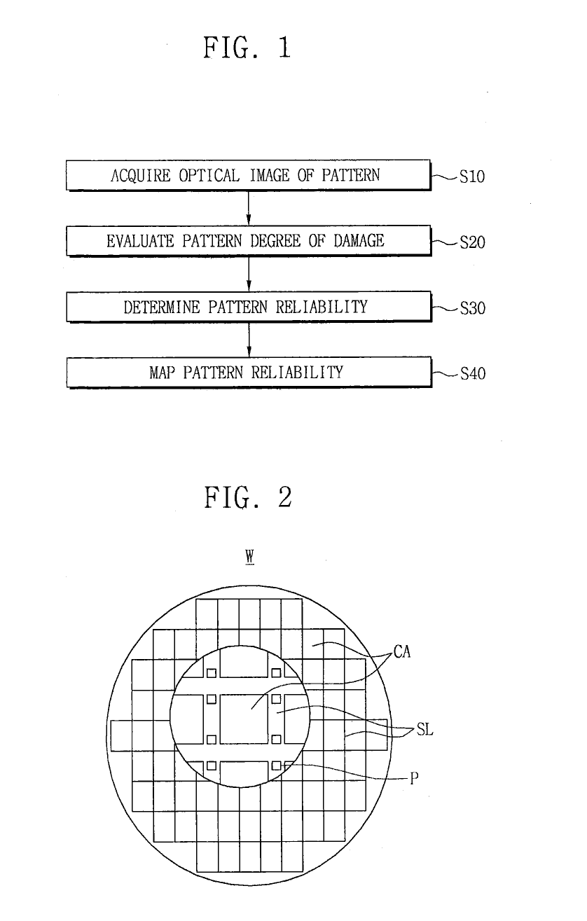

FIG. 1 is a flowchart illustrating a method of testing pattern reliability in accordance with some embodiments of inventive concepts.

Referring to FIG. 1, the method of testing pattern reliability in accordance with some embodiments of inventive concepts may include acquiring optical images of patterns on a wafer (S10), evaluating degrees of damage of the optical images corresponding to the patterns (S20), determining pattern reliability according to the degrees of damage (S30), and mapping the pattern reliability (S40). The acquisition of the optical images (S10) may include optically scanning a surface of the wafer on which at least one of various wafer manufacturing processes was performed.

FIG. 2 is a plan view schematically illustrating a wafer, on which a pattern is formed for a method of testing pattern reliability, according to some embodiments of inventive concepts.

Referring to FIGS. 1 and 2, a wafer W may include a plurality of chip areas CA, and scribe lanes SL between the chip areas CA. A plurality of patterns P may be formed in the scribe lanes SL. In order to manufacture a semiconductor device, the wafer W may be manufactured by performing various unit processes including a photolithography process, an etching process, and/or a chemical mechanical polishing (CMP) process. The patterns P may be used in a test to measure yield and/or accuracy in each process, and/or to monitor each process. As an example, the patterns P may be used in a topology measurement, a critical dimension (CD) measurement, and/or an overlay measurement. The optical images of the patterns P located in the scribe lanes SL may be acquired using a reflected light generated by radiating the wafer W with light, or using a scatterometer signal or spectrum of a reflected or scattered light generated by irradiating the wafer W with laser or radiation. The acquisition of the optical images (S10) may include acquiring the optical images of the patterns P located in the scribe lanes SL.

The evaluating of the degrees of damage of the patterns (S20) may include evaluating the patterns P formed on the scribe lanes SL in the acquired optical images. The patterns P may be damaged during the unit processes. As an example, the patterns P may be damaged in a CMP process, and/or by pattern failures in an etching process.

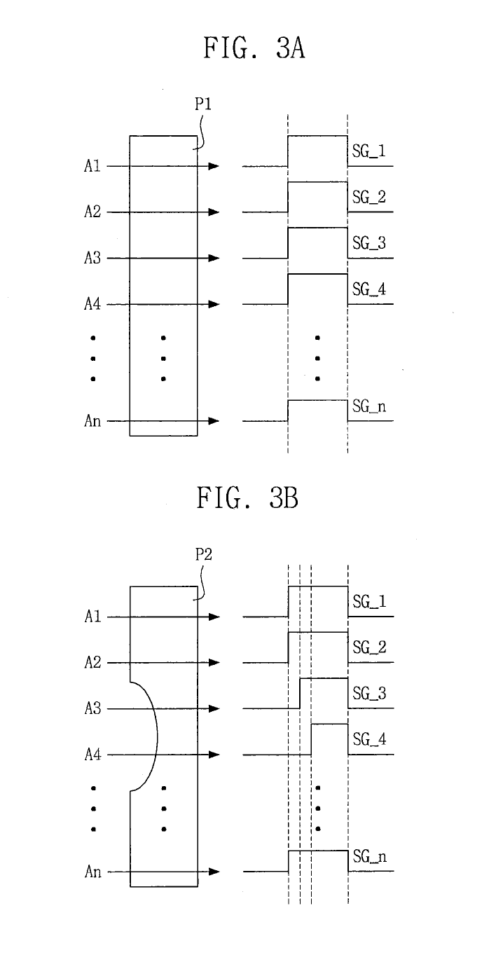

FIGS. 3A to 3C are signal waveforms illustrating signal values detected to test a deformation degree of a pattern in a method of testing pattern reliability according to some embodiments of inventive concepts. FIGS. 3A to 3C show patterns P1, P2, and P3, and optical signals of optical images thereof.

Referring to FIGS. 3A to 3C, FIG. 3A shows signal values SG_1 to SG_n detected from an undamaged normal pattern P1, FIG. 3B shows signal values SG_1 to SG_n detected from a pattern P2, of which a side surface is damaged, and FIG. 3C shows signal values SG_1 to SG_n detected from a pattern P3, of which a surface is damaged. The pattern P may be vertically divided into a plurality of areas A1 to An, optical image signals in the areas A1 to An may be analyzed, and the signal values SG_1 to SG_n in the areas A1 to An may be detected. The degree of damage of the pattern P may be evaluated by calculating a standard deviation through the following equation using the detected signal values SG_1 to SG_n in the areas A1 to An, and an average signal value of the patterns P1 to P3.

$$Damaged degree = \frac{1}{P {F}_{avg}} \int \sqrt{\frac{1}{N} {\sum }_{ N}^{ } [ {( P {F}_{P T} - P {F}_{avg} )}^{2} ]}$$

Here, PF_{avg} is an average signal value of the patterns P1, P2, and P3, and PF_{PT} is a signal value detected in any area An of the patterns P1, P2, and P3.

Referring to FIG. 3A, since the pattern P1 has no damaged part, the signal values SG_1 to SG_n detected in the areas A1 to An of the pattern P1 are the same. Referring to FIG. 3B, the signal values SG_1, SG_2, and SG_5 to SG_n detected in the areas A1, A2, and A5 to An, which have no damage, are the same, and the signal values SG_3 and SG_4 detected in the areas A3 and A4, in which side surfaces are damaged, have variations. Referring to FIG. 3C, the signal values SG_1 and SG_4 to SG_n detected in the areas A1 and A4 to An, which have no damage, are the same, and the signal values SG_2 and SG_3 detected in the areas A2 and A3, in which surfaces are damaged, have variations. To compare the degrees of damage of patterns evaluated through the above equation using the detected signal values shown in FIGS. 3A to 3C, the normal pattern P1 shown in FIG. 3A has a lesser degree of damage than the patterns P2 and P3 having damaged areas shown in FIGS. 3B and 3C.

Referring again to FIG. 1, the determination of the pattern reliability (S30) may include distinguishing reliable patterns from unreliable patterns according to the degrees of damage of the evaluated patterns P. For example, the pattern P having a degree of damage greater than a reference value among the degrees of damage of the patterns evaluated by the above equation may be distinguished as an unreliable pattern. The reference value may be set to the top percentage of a set reference percentage among the degrees of damage of the evaluated patterns P to distinguish an unreliable pattern. As an example, the reference value may be set to a top 10%, a top 20%, a top 30%, a top 50%, etc. In other words, the reference value may be set such that the top 10%, top 20%, top 30%, or top 50% of patterns with the greatest degrees of damage may be determined to be unreliable patterns. The remaining patterns may be determined to be reliable patterns for the purposes of the methods described.

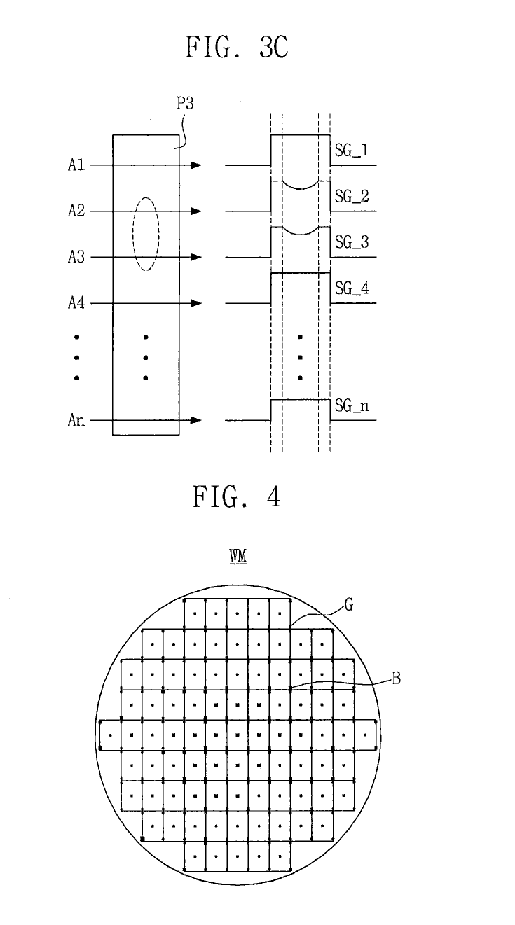

FIG. 4 is a plan view schematically illustrating a wafer map mapped by a method of testing pattern reliability according to some embodiments of inventive concepts.

Referring to FIGS. 1 and 4, the mapping of the patterns (S40) may map the reliable patterns and the unreliable patterns based on each position on the wafer according to the determined reliability of the patterns. FIG. 4 shows a wafer map WM in which a normal pattern is mapped in accordance with some embodiments of inventive concepts, and a reliable pattern G and an unreliable pattern B are separately mapped according to the positions of the patterns.

The method of testing pattern reliability in accordance with some embodiments of inventive concepts tests the pattern itself before testing through the pattern. Therefore, mismeasurement of the unreliable pattern including damage and/or failure may be reduced or prevented, and the reliability of a test result may be enhanced.

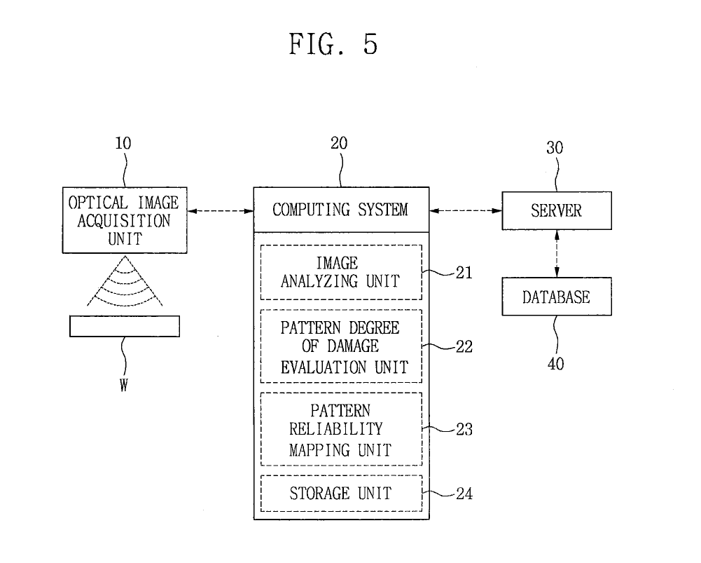

FIG. 5 is a block diagram schematically illustrating an apparatus of testing pattern reliability according to some embodiments of inventive concepts.

Referring to FIG. 5, the apparatus of testing pattern reliability in accordance with some embodiments of inventive concepts may include an optical image acquisition unit 10, a computing system 20, a server 30, and a database 40.

The optical image acquisition unit 10 may scan a surface of a wafer W, and then detect an optical image. As an example, the optical image acquisition unit 10 may acquire the optical image of the wafer W using a reflected light generated by radiating the wafer W with light, or using a scatterometer signal or spectrum of a reflected light generated by irradiating the wafer W with laser or radiation. The wafer W, as an example, may include a pattern formed on a scribe lane that divides chip areas.

The computing system 20 may analyze the image of the wafer detected from the optical image acquisition unit 10, and then determine and map reliability of the pattern. The computing system 20 may include a personal computer (PC), a work station, a server, and/or a controller configured to perform an operation in accordance with an embedded program. The computing system 20 may control an operation of the optical image acquisition unit 10 through communication with the optical image acquisition unit 10, and may receive the optical image detected from the optical image acquisition unit 10.

The computing system 20 may include an image analyzing unit 21, a pattern degree of damage evaluation unit 22, a pattern reliability mapping unit 23, and a storage unit 24.

The image analyzing unit 21 may analyze the optical image of the wafer received from the optical image acquisition unit 10. The image analyzing unit 21 may analyze the optical images of the patterns formed on each position on the wafer by analyzing the optical image. The image analyzing unit 21 may divide the optical image of the pattern into a number of areas, and detect a signal value of the image in each divided area.

The pattern degree of damage evaluation unit 22 may evaluate the reliability of the pattern using the signal values of the image detected by the image analyzing unit 21. The pattern degree of damage evaluation unit 22 may calculate a standard deviation of the signal value of the image in a number of the divided areas of the pattern, and an average value of detected signal values.

The pattern reliability mapping unit 23 may map the patterns into a wafer map by distinguishing reliable patterns from unreliable patterns according to the degrees of damage evaluated in the pattern degree of damage evaluation unit 22. The pattern reliability mapping unit 23 may determine the pattern as the unreliable pattern when a value thereof is greater than a reference value among the degrees of damage of the evaluated patterns.

The storage unit 24 may store data to operate the computing system 20 and/or data such as a test result. The storage unit 24 may store a mathematical calculation algorithm to analyze the optical image, and/or to evaluate the degree of damage of the pattern. The storage unit 24 may store data such as the reference value to determine the reliability of the pattern. The storage unit 24 may store wafer map data, or map history data in accordance with the test result.

The server 30 may receive data of the test result or transmit various information about test requirements of the wafer through communication with the computing system 20. The server 30 may include a PC, a work station, and/or a controller configured to perform an operation in accordance with an embedded program. The server 30 may reside on the personal computer (PC), work station, server, and/or controller of the computing system 20. The wafer information may include information of the process performed on the wafer.

The database 40 may store data transferred through the server 30, and various information about the wafer used in the test.

The computing system 20 and/or the server 30 may store necessary data input by a device operator and/or a process manager in the storage unit 24 and/or the database 40.

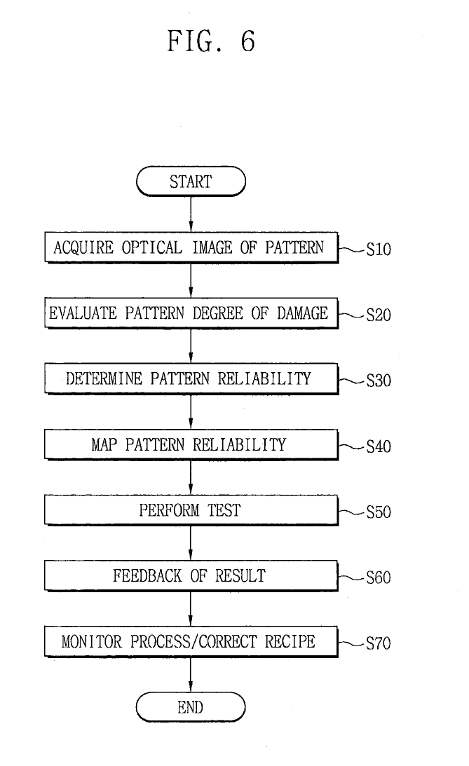

FIG. 6 is a flowchart illustrating a method of testing a semiconductor device using a pattern reliability test according to some embodiments of inventive concepts.

Referring to FIG. 6, the method of testing a semiconductor device using the pattern reliability test in accordance with some embodiments of inventive concepts may include acquiring optical images of patterns on a wafer (S10), evaluating degrees of damage of the patterns (S20), determining reliability of the patterns (S30), and mapping the reliability of the patterns (S40), performing a test (S50), feedback of a result (S60), and monitoring a process and correcting a recipe (S70).

The acquisition of the optical images on the wafer (S10), the evaluation of the degrees of damage of the patterns (S20), the determining of the pattern reliability (S30), and the mapping of the pattern reliability (S40) will be understood with reference to FIG. 1.

The performing of the test (S50) may test accuracy and/or yield of a unit process performed on the wafer with reference to the mapped wafer map. The performing of the test (S50) may be performed with the pattern of a position mapped to a reliable pattern on the wafer map. The performing of the test (S50) may remove test result values for the patterns of positions mapped to unreliable patterns after performing the test on the patterns. The performing of the test (S50) may include an overlay measurement between continuous layers formed to the pattern, and/or a CD measurement of a photoresist pattern when a unit process performed on the wafer, as an example, is a photolithography process. The overlay measurement and/or the CD measurement may be performed after a photoresist layer is formed on the wafer and an exposure process is performed to form the pattern, and performed by measuring latent images of an exposed photoresist area and an unexposed photoresist area. The overlay measurement and/or the CD measurement may be performed after a baking process is performed on the wafer including the exposed photoresist layer. The overlay measurement and/or the CD measurement may be performed by measuring the photoresist pattern formed on the wafer after a patterning process including an exposure process and a developing process is performed on the wafer. The performing of the test (S50) may include a CD measurement when a unit process performed on the wafer, as an example, is an etching process, and may include a topology measurement in a case of a CMP process.

The feedback of the result (S60) may transfer result data performed by performing the test (S50) to a unit process equipment and/or a user such as an equipment operator, a process engineer, or the like. The feedback of the result (S60) may transfer test result values of the reliable patterns in accordance with each position of the wafer map.

The monitoring of the process and the correction of the recipe (S70) may monitor accuracy and/or yield of the unit process performed on the wafer with reference to the test result value received through the feedback of the result (S60), and correcting a recipe of the process and/or the device according to a result of the monitoring. In the monitoring of the process and the correction of the recipe (S70), a cause of an error may be determined according to information of the position in which the error occurs on the wafer map, with reference to the received test result values on the wafer map, and a unit process recipe and/or device recipe may be corrected according to a determined result. Therefore, error occurrence on the wafer may be reduced in a subsequent process. As an example, when an error is detected in which a position of a wafer is twisted in one direction, the photolithography process may be updated to rotate the wafer to an appropriate position to correct the error. Therefore, the error caused from twisting may be prevented in the subsequent process.

The method of testing a semiconductor device using the pattern reliability test in accordance with some embodiments of inventive concepts may include performing a test on only reliable patterns through the pattern reliability test, and thus the reliability of the test result may be improved. As the unit process and/or an operation of the device is controlled with reference to the reliable test result, accuracy and/or yield of the unit process performed on the wafer may be improved.

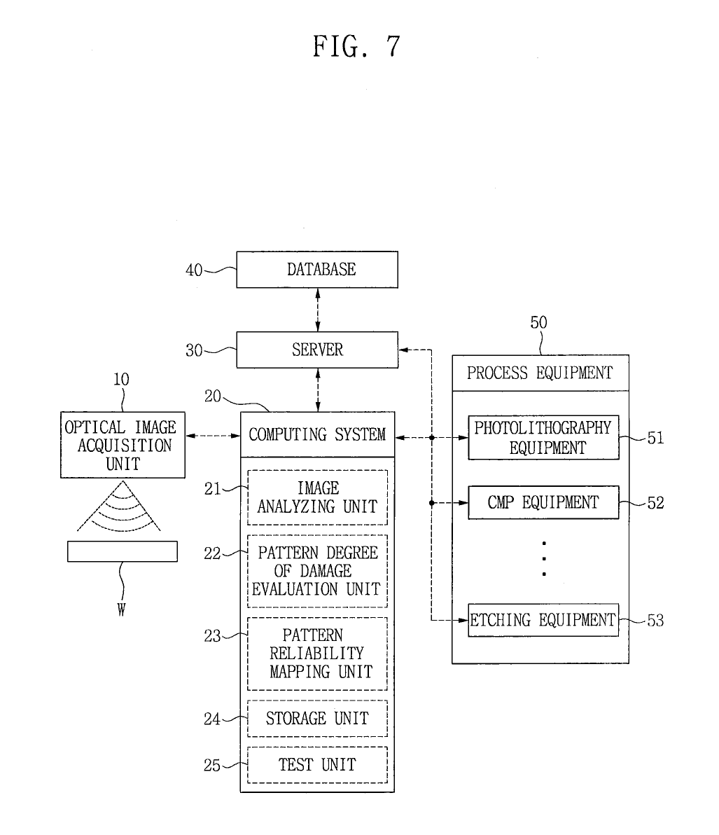

FIG. 7 is a block diagram schematically illustrating an apparatus of testing a semiconductor device using a pattern reliability test according to some embodiments of inventive concepts.

Referring to FIG. 7, the device of testing a semiconductor device using the pattern reliability test in accordance with some embodiments of inventive concepts may include an optical image acquisition unit 10, a computing system 20, a server 30, a database 40, and process equipment 50.

The optical image acquisition unit 10, the computing system 20, the server 30, and the database 40 will be understood with reference to FIG. 5.

The computing system 20 may include a test unit 25 that may perform a test, such as an overlay measurement, a CD measurement, a topology measurement, or the like, on a pattern corresponding to a position of a reliable pattern with reference to the wafer map performed by the pattern reliability mapping unit 23.

The process equipment 50 may perform a unit process for the semiconductor device, and may include photolithography equipment 51, CMP equipment 52, and/or etching equipment 53. The process equipment 50 may perform a unit process on the wafer, transfer information thereof to the computing system 20 and/or the server 30, and perform a unit process on the wafer by a corrected recipe received from the computing system 20 and/or the server 30. The correction of the recipe may be performed to monitor the process through the result value received from the test unit 25 and to remove an error of the process and/or the device. The correction and storing of the recipe may be remotely performed at the computing system 20, the server 30, the process equipment 50, and/or another location. The process equipment 50 may be configured of a cell including a single device or multiple devices. As an example, the photolithography equipment 51 may be configured of a single cell of exposure equipment, developing equipment, baking equipment, and the like. The process equipment 50 may be configured of a single device, or a single cell including the optical image acquisition unit 10 and the computing system 20.

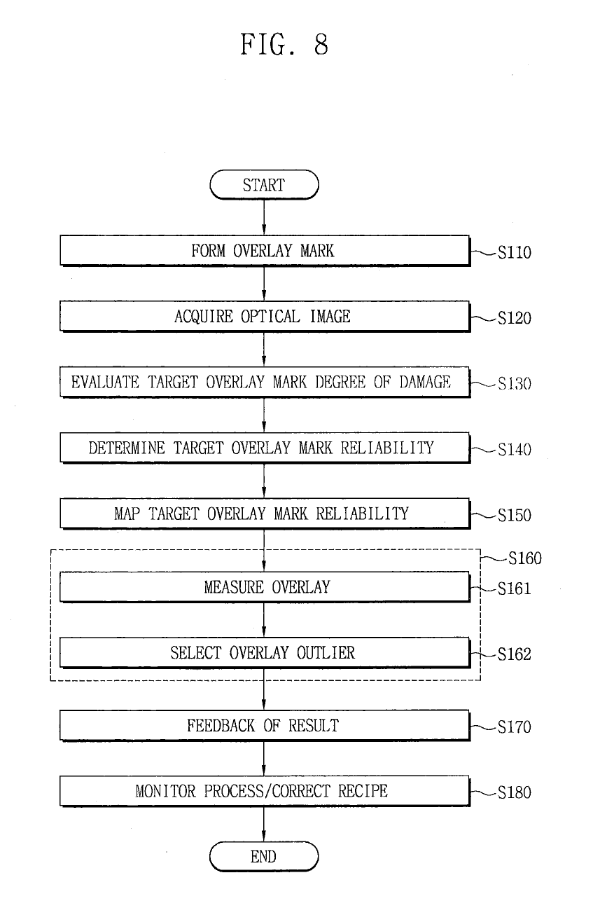

FIG. 8 is a flowchart illustrating a method of measuring an overlay using pattern reliability test according to some embodiments of inventive concepts.

Referring to FIG. 8, the method of measuring the overlay using the pattern reliability test in accordance with some embodiments of inventive concepts may include forming an overlay mark (S110), acquiring an optical image of the overlay mark (S120), evaluating a degree of damage of a target overlay mark (S130), determining a reliability of the target overlay mark (S140), mapping the reliability of the target overlay mark (S150), performing an overlay test (S160), feedback of a result (S170), and monitoring a process and correcting a recipe (S180).

The formation of the overlay mark (S110) may include forming a target pattern and forming a compare pattern in a scribe lane SL of a wafer W, in which a unit process is performed on a chip area CA, as shown in FIG. 2. The overlay mark may be formed to check a location for performing the unit process using an arrangement of the compare pattern with the target pattern.

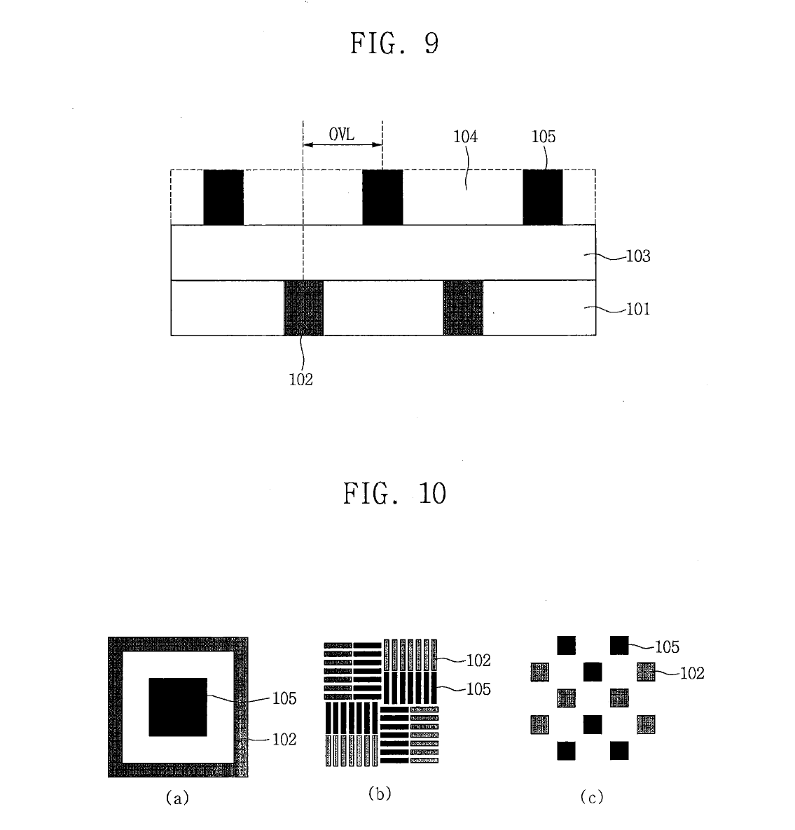

FIG. 9 is an cross-sectional view schematically illustrating a wafer during formation of an overlay mark in a method of measuring an overlay using the method of testing pattern reliability according to some embodiments of inventive concepts.

Referring to FIG. 9, the overlay mark of the wafer W may include a target overlay mark 102, which may be used as a target pattern of the overlay mark, in a lower thin layer 101, and may include an upper overlay mark 105, which may be used as a compare pattern of the over lay mark, on an upper thin layer 103. A formation of the upper overlay mark 105 may include coating a photoresist on the entire wafer W having the upper thin layer 103, performing an exposure process of the photoresist to form an exposed area and an unexposed area, and developing the exposed photoresist to remove the exposed area or the unexposed area. The coat of the photoresist, the performance of the exposure process, and the development of the photoresist may be performed in the photolithography equipment 50 shown in FIG. 7. After the development of the exposed photoresist, the remaining area may become the upper overlay mark 105. The removed area 104 by the development process may be the exposed area or the unexposed area of the photoresist based on a positive or negative characteristic of the photoresist. The formation of the upper overlay mark 105 may further include baking the photoresist exposed in the photolithography equipment 51.

FIG. 10 provides plan views illustrating overlay marks in a method of measuring an overlay using the method of testing pattern reliability in accordance with some embodiments of inventive concepts.

Referring to FIG. 10, the overlay mark may be formed in various forms such as a box-in-box (BiB) mark (a), an advanced imaging metrology mark (AIM) (b), a blossom mark (c), etc.

Referring again to FIG. 8, as described in the embodiments of FIG. 1, the optical image may be acquired by scanning the surface of the wafer on which the overlay mark is formed on the scribe lane (S120).

The target overlay mark 102 may be variously damaged in a previous process in which the pattern is formed. A unit process may be performed based on a chip area, and thus the target overlay mark 102 formed on the scribe lane may be relatively seriously damaged. As an example, the target overlay mark 102 may have pattern damage during a CMP process, an etching process, or the like. A degree of damage of the target overlay mark 102 may be evaluated in the acquired optical image as described in the embodiments of FIG. 1 in order to check the degree of damage of the target overlay mark 102 damaged in the previous process (S130). When the target overlay mark 102 is formed as multiple patterns, a standard deviation of each pattern may be calculated according to the embodiments of FIG. 1, the calculated standard deviations of the patterns are averaged, and thus the degree of damage may be evaluated. When the target overlay mark 102 is mixed in a horizontal direction and in a vertical direction, a standard deviation of the pattern in each direction is calculated, the calculated standard deviations in each direction are averaged, and thus the degree of damage may be evaluated.

The determining of a reliability of the target overlay mark (S140) may distinguish a reliable pattern and an unreliable pattern according to the degrees of damage of the evaluated target overlay marks 102 as described in the embodiments of FIG. 1.

The reliability mapping of the target overlay mark (S150) may map to the wafer map WM as shown in FIG. 4 according to the reliability of the target overlay mark. As the position of the target overlay mark 102 determined as the unreliable pattern is confirmed according to information of the wafer map WM, monitoring for the previous process such as a CMP process that causes pattern damage, may be performed.

The performing of an overlay test (S160) may include checking an arrangement of the upper overlay pattern 105 with the target overlay pattern 103. For example, the performing of the overlay test (S160) may include measuring an overlay OVL, that is a degree of an overlap between the target overlay mark 102 and the upper overlay mark 105 shown in FIG. 9. For example, the performing of the overlay test (S160) may include measuring a horizontal location of the upper overlay mark 105 based on the target overlay mark 102 shown in FIG. 10. An overlay error, as an example, may be caused from a position detection error of the target by a change in a forming process of the target overlay mark 102, and/or changing a thickness of the photoresist. The overlay error, as an example, may be caused from torsion, and/or a change of a reduction ratio in accordance with changing a pressure in a stepper resulting from performing the exposure process using multiple steppers in the photolithography process.

The performing of the overlay test (S160) may include measuring the overlay (S161) and selecting an overlay outlier (S162). The measurement of the overlay (S161) may measure an overlay value by overlaying and averaging signals detected from the target overlay mark 102 and the upper overlay mark. The selection of the overlay outlier (S162) may select a value greater than a set value or a statistical reference value among the detected overlay values. The performing of the overlay test (S160) may measure at only the position mapped to the reliable pattern of the wafer map, and/or use only data having a value of the position mapped to the determined reliable pattern resulting from the measurement. The performing of the overlay test (S160) may apply overlay values at the position mapped to the reliable pattern except a value selected as the overlay outlier to a model of an exponentially weighted moving average (EWMA) or a linear model predictive control (LMPC), and then extracting a correction value for removing the overlay error.

The feedback of the result (S170) may transfer the test result value to know by the photolithography equipment and/or a user.

The monitoring of the process and correction of the recipe (S180) may monitor accuracy and/or yield of the unit process performed on the wafer with reference to the overlay test result value received through the feedback of the result (S170) by the user, and correct a recipe of the process and/or the photolithography equipment according to the result of the monitoring. In the monitoring of the process and correction of the recipe (S180), the photolithography equipment corrects the process recipe according to the correction value depending on the overlay test result value so that a unit process is performed on a subsequently loaded wafer. In the monitoring of the process and correction of the recipe (S180), as a residual overlay error in accordance with the corrected result is monitored, the overlay that directly affects yield and throughput of the unit process may be managed.

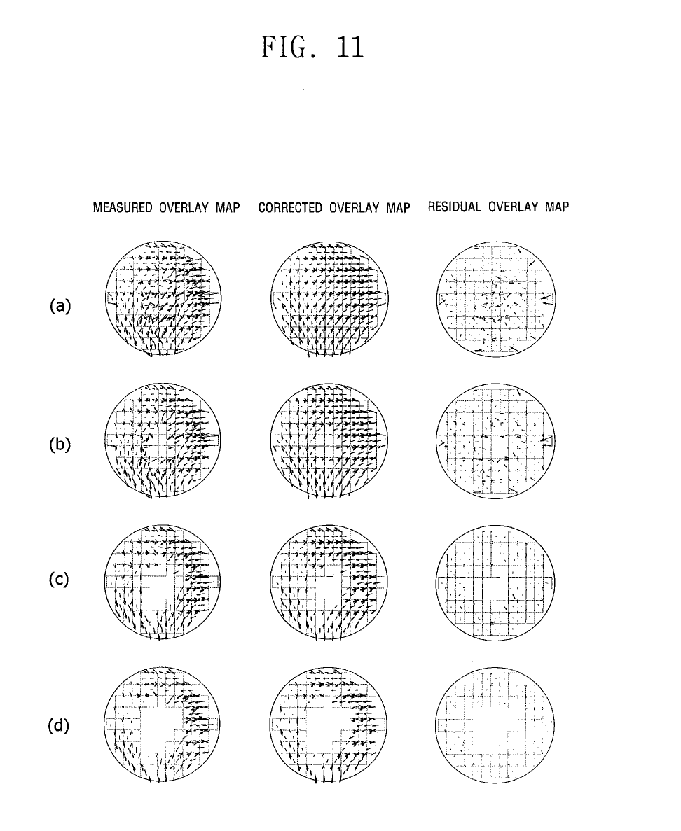

FIG. 11 provides wafer maps illustrating measured overlay values, corrected overlay values, and residual overlay values in a method of measuring an overlay using the method of testing pattern reliability according to some embodiments of inventive concepts.

Referring to FIG. 11, the wafer maps illustrate initial overlay values measured from a wafer on which a subsequent process is performed, overlay values corrected by a correction value, and residual overlay values after the correcting through a method of measuring an overlay using the method of testing pattern reliability as discussed with reference to FIG. 8. FIG. 11 (a) illustrates a result when a reference value of the pattern reliability test is not set, FIG. 11 (b) illustrates a result when the reference value is set to a top 10%, FIG. 11 (c) illustrates a result when the reference value is set to a top 30%, and FIG. 11 (d) illustrates a result when the reference value is set to a top 50%.

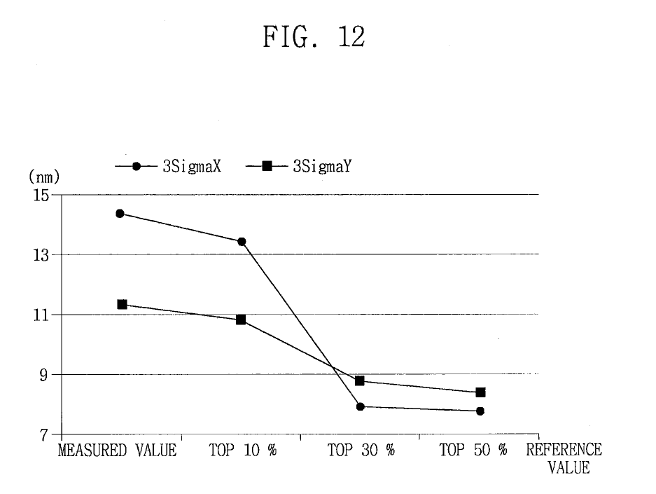

FIG. 12 is a graph of residual overlay values according to a reference value for checking pattern reliability in a method of measuring an overlay using the methods of testing pattern reliability in accordance with some embodiments of inventive concepts.

Referring to FIGS. 11 and 12, when the overlay is measured by setting the reference value to the top 30%, the residual overlay of values may be improved by about 2 nm to 6 nm in comparison to when the reliability of the pattern is not mapped (measurement value).

The method of testing pattern reliability and the method of testing the semiconductor device using the same in accordance with various embodiments of inventive concepts can reduce or prevent a mismeasurement caused from the damage of unreliable patterns, and the like, and improve the reliability of the test result, as the test is performed only on the reliable pattern after the test of the pattern reliability is performed to monitor the semiconductor manufacturing process.

The method of testing pattern reliability and the method of testing the semiconductor device using the same in accordance with various embodiments of inventive concepts can improve the accuracy of the correction model, and thus the yield of the semiconductor manufacturing process, as the reliable test result is used to control the process in accordance with the test result when the correction model is applied.

The foregoing is illustrative of embodiments and is not to be construed as limiting thereof. Although a few embodiments have been described, those skilled in the art will readily appreciate that many modifications are possible in embodiments without materially departing from the novel teachings and advantages. Accordingly, all such modifications are intended to be included within the scope of present inventive concepts as defined in the claims. In the claims, means-plus-function clauses are intended to cover the structures described herein as performing the recited function, and not only structural equivalents but also equivalent structures. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

What is claimed is:

1. A method of testing pattern reliability, comprising:
acquiring an optical image of a wafer on which a plurality of patterns are formed;
evaluating respective degrees of damage of ones of the plurality of patterns based on the optical image;
determining a respective reliability of the ones of the plurality of patterns according to the evaluated respective degrees of damage; and
mapping the reliability of the ones of the plurality of patterns based on locations of the respective patterns on the wafer.

2. The method according to claim 1, wherein the evaluating of the degree of damage comprises:
dividing the ones of the plurality of patterns into a number of divided areas;
detecting a respective signal value for each of the divided areas from the acquired optical image; and
calculating a respective standard deviation for the ones of the plurality of patterns using the detected signal values and an average signal value of the detected signal values.

3. The method according to claim 1, wherein the determining of the reliability of the patterns comprises determining a pattern to be an unreliable pattern when a degree of damage thereof is greater than a reference degree of damage.

4. The method according to claim 3, wherein the mapping of the reliability comprises distinguishing a pattern determined to be reliable and a pattern determined to be unreliable on a map based on the respective locations of the pattern determined to be reliable and the pattern determined to be unreliable according to the reliability of the determined ones of the plurality of patterns.

5. A method of testing a semiconductor device using a pattern reliability test, comprising:
acquiring an optical image of a wafer on which a plurality of patterns are formed;
evaluating respective degrees of damage of ones of the plurality of patterns based on the optical image;
determining respective reliabilities of the ones of the plurality of patterns according to the evaluated respective degrees of damage;
mapping the reliabilities of the ones of the plurality of patterns based on locations of the respective patterns on the wafer;
performing a test on the mapped patterns; and
correcting a recipe used to perform a process according to a result of the test.

6. The method according to claim 5, wherein the performing of the test comprises performing the test on patterns mapped as reliable patterns among the mapped patterns.

7. The method according to claim 5, wherein the performing of the test comprises removing result values of the test corresponding to patterns mapped as unreliable patterns after performing the test on the mapped patterns.

8. The method according to claim 5, wherein the ones of the patterns comprise a respective overlay mark.

9. The method according to claim 8, wherein the evaluating of the respective degrees of damage of the ones of the plurality of patterns comprises evaluating the respective degrees of damage of respective target overlay marks of the respective overlay marks.

10. The method according to claim 9, further comprising:
monitoring a unit process performed on the target overlay mark to determine a cause of an error.

11. The method according to claim 10, wherein the unit process comprises at least one of a chemical mechanical polishing (CMP) process and an etching process.

12. The method according to claim 8, wherein the determining of the reliability of the patterns comprises determining a set percentage of the ones of the patterns with the highest degrees of damage to be unreliable and determining the remaining patterns to be reliable.

13. The method according to claim 12, wherein the set percentage is around 30% or more.

14. The method according to claim 8, wherein the correcting of the recipe corrects the recipe with respect to a photolithography process.

15. The method according to claim 8, wherein the performing of the test comprises:
measuring an overlay; and
selecting an outlier degree of damage having a degree of damage greater than a set degree of damage or greater than a statistical reference degree of damage among the measured degrees of damage.

16. A method comprising:
acquiring an optical image of a wafer comprising a plurality of overlay marks;
evaluating respective degrees of damage of ones of the plurality of overlay marks based on the optical image;
selecting a reliable overlay mark from the ones of the plurality of overlay marks based on the evaluated degrees of damage; and
correcting a recipe of a process for producing wafers based on the reliable overlay mark.

17. The method according to claim 16,
wherein the plurality of overlay marks comprises a plurality of target overlay marks and a plurality of upper overlay marks on the plurality of the target overlay marks, and
wherein evaluating respective degrees of damage comprises measuring respective degrees of an overlap between ones of the plurality of target overlay marks and corresponding ones of the plurality of upper overlay marks.

18. The method according to claim 16, wherein the ones of the plurality of overlay marks comprise a respective plurality of patterns and wherein the evaluating respective degrees of damage of ones of the plurality of overlay marks comprises averaging standard deviations of signal values of the respective plurality of patterns based on the acquired optical image.

19. The method according to claim 16, wherein the correcting the recipe of the process comprises:
measuring a plurality of signals detected from the reliable overlay mark;
selecting an overlay outlier from the plurality of signals, wherein the value of the overlay outlier is greater than a set value or a statistical reference value;
determining an overlay value by overlaying and averaging ones of the plurality of signals that are not selected as the overlay outlier.

20. The method according to claim 16, wherein evaluating respective degrees of damage of ones of the plurality of overlay marks comprises calculating a standard deviation of a plurality of detected signal values corresponding to a plurality of areas of a respective one of the plurality of overlay marks based on the optical image.
